(19) United States
(12) Patent Application Publication
(10) Pub. No.: US 2005/0088081 A1
(43) Pub. Date: Apr. 28, 2005

(54) Organic electroluminescent device

(75) Inventors: Ryuji Nishikawa, Gifu-shi (JP); Tetsuji Omura, Ogaki-shi (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 10/944,413

(22) Filed: Sep. 20, 2004

(30) Foreign Application Priority Data
Sep. 30, 2003 (JP) 2003-340652

(51) Int. Cl. H05B 33/14

(52) U.S. Cl. 313/504; 313/503; 313/506

(57) ABSTRACT

This invention provides an organic EL device of optical resonator type where diffusion of an Ag material caused by heat generated in a manufacturing process and while light is being emitted is minimized so as to stabilize characteristics of a driving TFT. In the organic EL device of optical resonator type of the invention, an anti-diffusion layer (made of ITO or IZO) connected with the driving TFT (not shown) is formed on a glass substrate, and a semi-transmissive film (made of an Ag alloy layer) having a predetermined film thickness enabling semi-transmission of light, a transparent anode (an electrode made of ITO or IZO), an organic EL layer (e.g. made of a hole transport layer, an emissive layer, and an electron transport layer), and a cathode (made of an Ag alloy layer) serving as a reflection film having a predetermined film thickness enabling reflection of light are formed on the anti-diffusion layer in this order. The anti-diffusion layer inhibits thermal diffusion of the Ag material of the semi-transmissive film.

### CROSS-REFERENCE OF THE INVENTION

This invention is based on Japanese Patent Application No. 2003-340652, the content of which is incorporated by reference in its entirety.

### BACKGROUND OF THE INVENTION

1. Field of the Invention

This invention relates to an organic electroluminescent device, particularly, to an organic electroluminescent device of optical resonator type.

2. Description of the Related Art

Conventionally, an organic electroluminescent (hereafter, referred to as EL) element of optical resonator type where color purity and luminance of emitting light are improved has been known.

In the organic EL device of optical resonator type, an organic EL layer is interposed between a reflection film serving as an electrode enabling reflection of light emitted from the organic EL layer and a semi-transmissive film enabling transmission of the light toward a light emitting surface and reflection of the light toward a side of the organic EL layer, thereby resonating a predetermined wavelength component of the light emitted from the organic EL layer. Accordingly, only a predetermined wavelength region of the light emitted from the organic EL layer can be extracted and released from a glass substrate side (or a cathode side), so that the color purity (brightness of color) and the luminance of the released light can be improved.

Next, a basic structure of the organic EL device of optical resonator type of the conventional art described above will be described with reference to FIG. 3, which is a schematic cross-sectional view showing the structure of the organic EL device of the conventional art. Note that FIG. 3 shows a simplified view of the organic EL device of bottom emission type connected with a driving TFT (thin film transistor) on a glass substrate.

As shown in FIG. 3, a semi-transmissive film 31 made of an Ag (silver) alloy layer is formed on a glass substrate 30. Although not shown, the semi-transmissive film 31 is connected with a drain electrode (or a source electrode) of the driving TFT (not shown) formed on the glass substrate 30. The semi-transmissive film 31 has a function as a half mirror, which transmits light toward the glass substrate 30 and reflects light toward the side opposite from the glass substrate 30.

A transparent anode 32 made of, for example, ITO (indium tin oxide) is formed on the semi-transmissive film 31. An organic EL layer 33 includes a hole transport layer, an emissive layer, an electron transport layer and so on is formed on the transparent anode 32. A cathode 34 made of an Ag alloy layer is formed on the organic EL layer 33. The cathode 34 serves as a reflection film for reflecting light emitted from the organic EL layer 33 toward the organic EL layer 33.

Under the above structure, light emitted from the organic EL layer 33 is repeatedly reflected through a reflection route between the cathode 34 serving as a reflection film and the semi-transmissive film 31, thereby resonating a predetermined wavelength component of the light. For obtaining light in a desired predetermined wavelength region, the length of the reflection route between the semi-transmissive film 31 and the cathode 34 is adjusted by forming each of the transparent anode 32 and the organic EL layer 33 to have a predetermined film thickness which differs among desired wavelengths.

Relevant technology is disclosed in the Japanese Patent Application Publication No. 2003-123987.

However, in the organic EL device of optical resonator type of the conventional art, since the Ag material forming the Ag (silver) alloy layer of the semi-transmissive film 31 is adjacent to the glass substrate 30 and is thermally unstable, the Ag material is diffused by heat generated in a manufacturing process of the device and while light is being emitted. This causes a problem of a change in a threshold value of the driving TFT connected with the semi-transmissive film 31 of the organic EL device.

### SUMMARY OF THE INVENTION

This invention is directed to an organic EL device of optical resonator type which can minimize diffusion of an Ag material caused by heat generated in a manufacturing process and while light is being emitted and a change in characteristics of the driving TFT.

The invention provides an organic electroluminescent device that includes a glass substrate, a thin film transistor disposed on the glass substrate, an anti-diffusion layer disposed on the glass substrate and connected to the thin film transistor, a first silver alloy layer disposed on the anti-diffusion layer, an electrode disposed on the first silver alloy layer, an organic electroluminescent layer disposed on the electrode, and a second silver alloy layer disposed on the organic electroluminescent layer.

The invention also provides an organic electroluminescent device that includes a glass substrate, a thin film transistor disposed on the glass substrate, a first conducting inorganic layer disposed on the glass substrate and connected to the thin film transistor, a first metal layer disposed on the first conducting inorganic layer, a second conducting inorganic layer disposed on the first metal layer, an organic electroluminescent layer disposed on the second conducting inorganic layer, and a second metal layer disposed on the organic electroluminescent layer.

### BRIEF DESCRIPTION OF THE DRAWINGS

FIG. 1 is a schematic cross-sectional view of an organic EL device of an embodiment of the invention.

FIG. 2 is a cross-sectional view of the organic EL device and a driving TFT of FIG. 1.

FIG. 3 is a schematic cross-sectional view of an organic EL device of a conventional art.

### DETAILED DESCRIPTION OF THE INVENTION

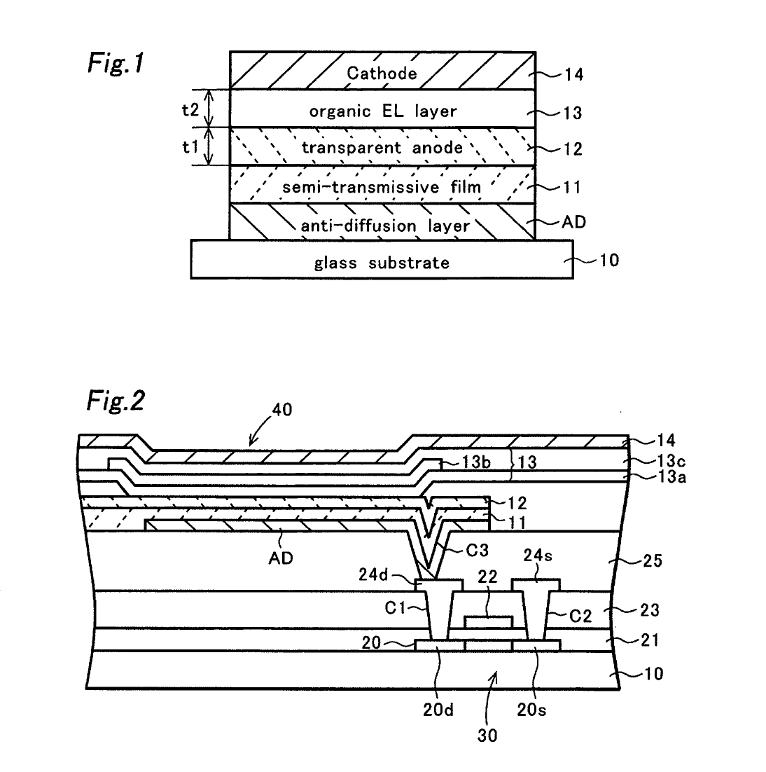

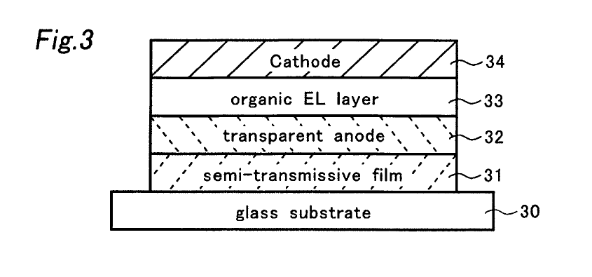

Next, a structure of an organic EL device of an embodiment of the invention will be described with reference to drawings. FIG. 1 is a schematic cross-sectional view showing a basic structure of the organic EL device of the embodiment of the invention. Note that FIG. 1 shows a simplified view of the organic EL device of bottom emission type connected with a driving TFT (thin film transistor), which is shown in FIG. 2.

As shown in FIG. 1, an anti-diffusion layer AD is formed on a glass substrate 10. The anti-diffusion layer AD is a transparent electrode made of ITO (indium tin oxide) or IZO (indium zinc oxide). Although not shown, the anti-diffusion layer AD is electrically connected with a drain electrode (or a source electrode) of a driving TFT (not shown) formed on the glass substrate 10.

A semi-transmissive film 11 is formed on this anti-diffusion layer AD. The semi-transmissive film 11 has a function of a half mirror which transmits light toward the glass substrate 10 and reflects light toward the side opposite form the glass substrate 10. This semi-transmissive film 11 is made of an Ag (silver) alloy layer. It is preferable that this Ag alloy layer is made of Ag—Pd—Cu (alloy made of silver, palladium, and copper) or Ag—Nd—Cu (alloy made of silver neodymium, and copper), for example. A reason why the semi-transmissive film 11 is preferably made of the Ag alloy layer is that the Ag alloy can be easily thinned to have a predetermined film thickness enabling semi-transmission of light and has an appropriate rate of light reflection compared with the other metals.

A transparent anode 12 connected with a power supply voltage (not shown) is formed on the semi-transmissive film 11. The transparent anode 12 is a transparent electrode made of ITO or IZO.

An organic EL layer 13 including a hole transport layer 13a, an emissive layer 13b, an electron transport layer 13c and so on is formed on the transparent anode 12. The hole transport layer 13a, the emissive layer 13b, and the electron transport layer 13c are formed to have a structure described below, for example.

That is, the hole transport layer 13a is made of a first hole transport layer made of MTDATA (4, 4, 4-tris (3-methylphenylphenylamino) triphenylamine) and a second hole transport layer made of TPD (4, 4-bis (3-methylphenylphenylamino) biphenyl). The emissive layer 13b is made of Bebq² (bis(10-hydroxybenzo[h]quinolinato)beryllium) containing quinacridone, and the electron transport layer 13c is made of Bebq2.

A cathode 14 connected with a power supply voltage (not shown) is formed on the organic EL layer 13. The cathode 14 serves as a reflection film for reflecting light emitted from the organic EL layer 13 toward the side of the organic EL layer 13.

This cathode 14 is made of an Ag (silver) alloy layer similar to the semi-transmissive film 11. It is preferable that this Ag alloy layer is made of Ag—Pd—Cu (alloy made of silver, palladium, and copper) or Ag—Nd—Cu (alloy made of silver neodymium, and copper), for example.

A reason why the cathode 14 is preferably made of the Ag alloy layer is that the Ag alloy has an appropriate rate of light reflection compared with the other metals and thus is suitable as a reflection film.

In the organic EL device of optical resonator type described above, for obtaining light in a desired predetermined wavelength region, a length of a reflection route between the semi-transmissive film 11 and the cathode 14 serving as the reflection film is adjusted by forming each of a film thickness t1 of the transparent anode 12 and a film thickness t2 of the organic EL layer 13 to have a predetermined film thickness, which differs among desired wavelengths.

Next, description will be made on a light emitting process of the organic EL device of optical resonator type of the embodiment of the invention. When the driving TFT connected with the organic EL device turns on, the organic EL layer 13 emits light by a current supplied from the power supply voltage through the transparent anode 12 and the cathode 14. That is, in the organic EL device, holes injected from the transparent anode 12 and electrons injected from the cathode 14 are recombined inside the organic layer 13. These recombined holes and electrons generate excitons by excitation of organic molecules forming the organic layer 13. Light is emitted from the organic layer 13 in a process of radiation of the excitons.

Furthermore, this light is repeatedly reflected through the reflection route between the cathode 14 as the reflection film and the semi-transmissive film 11. Therefore, a predetermined wavelength component of the light is resonated, and thus light in a predetermined wavelength region is extracted and released from the glass substrate 10, which is the transparent substrate, through the semi-transmissive film 11.

Then, the heat generated while light is being emitted in the organic EL device makes the Ag material forming the semi-transmissive film 11 start diffusing. However, the anti-diffusion layer AD is formed under the semi-transmissive layer 11 so that the thermal diffusion of the Ag material of the semi-transmissive film 11 is inhibited in the anti-diffusion layer AD without approaching to a contact portion between the organic EL stack and the driving TFT. Therefore, a change in characteristics of the driving TFT (e.g. a shift in a threshold value) can be minimized.

The effect of the anti-diffusion layer AD is not limited to the inhibition of thermal diffusion of the Ag material caused by heat generated while light is being emitted in the organic EL device. When the organic EL device described above is formed on the glass substrate 10, the anti-diffusion layer AD is effective for inhibiting thermal diffusion of the Ag material caused by thermal processing in a manufacturing process. That is, when the Ag alloy layer (the semi-transmissive layer 11 in the organic EL device of bottom emission type) is formed, the diffusion of the Ag material to the driving TFT caused by the thermal processing can be minimized by the anti-diffusion layer AD, so that the change in the characteristics of the driving TFT (e.g. a shift in a threshold value) can be minimized.

Next, an example of the structure of the organic EL device of optical resonator type connected with the driving TFT will be described in detail with reference to FIG. 2, which is a cross-sectional view showing a concrete structure of the organic EL device of the embodiment of the invention. Note that FIG. 2 shows a driving TFT 30 (thin film transistor) provided in a pixel portion of a display device and an organic EL element 40 of bottom emission type connected to the driving TFT 30.

As shown in FIG. 2, an active layer 20 made of polysilicon is formed on the transparent glass substrate 10. A gate electrode 22 is formed above the active layer 20 with the gate insulating film 21 interposed therebetween. An insulating film 23 is formed on the gate insulating film 21 and the gate electrode 22.

A contact hole Cl is provided in the gate insulating film 21 and the insulating film 23 in a position corresponding to a drain region 20d of the active layer 20. A drain electrode 24d is embedded in the contact hole C1. Furthermore, a contact hole C2 is provided in the gate insulating film 21 and the insulating film 23 in a position corresponding to a source region 20s of the active layer 20. A source electrode 24s is embedded in the contact hole C2.

An interlayer insulating film 25 is formed on the insulating film 23, the drain electrode 24d and the source electrode 24s.

A contact hole C3 is provided in the interlayer insulating film 25 in a position corresponding to the drain electrode 24d. The anti-diffusion layer AD is formed on a part (or the whole surface) of the interlayer insulating film 25 including the contact hole C3. The anti-diffusion layer AD is electrically connected with the drain electrode 24d exposed to a bottom portion of the contact hole C3. The semi-transmissive film 11 is formed on a part (or the whole surface) of the anti-diffusion layer AD. The transparent anode 12 is formed on the semi-transmissive film 11 and the anti-diffusion layer AD (or the semi-transmissive film 11). The organic EL layer 13 is formed on the transparent anode 12. The organic EL layer 13 includes, for example, the hole transport layer 13a, the emissive layer 13b and the electron transport layer 13c. The cathode layer 14 serving as the reflection film is formed on the organic EL layer 13.

In the embodiment described above, the organic EL layer 13 has a three-layered structure formed of the hole transport layer 13a, the emissive layer 13b and the electron transport layer 13c. However, the embodiment is not limited to this and the organic EL layer 13 can have a multiple-layered structure formed of others (e.g. formed of a hole injection layer and an electron injection layer in addition to the above three layers) or a single layered structure (formed of an emissive layer).

In the embodiment described above, the organic EL device is of bottom emission type. However, the embodiment is not limited to this, and the organic EL device can be of top emission type.

That is, in the embodiment described above, alternatively, the semi-transmissive film 11 made of an Ag alloy layer can be replaced by a reflection film having a predetermined film thickness enabling reflection of light, and the cathode 14 serving as a reflection film made of an Ag alloy layer can be replaced by the cathode (half transparent cathode) serving as a semi-transmissive film having a predetermined film thickness enabling semi-transmission of light. In this case, a predetermined wavelength region of light emitted from the organic EL layer is extracted by resonating a predetermined wavelength component through a reflection route between the reflection film and the semi-transmissive film, and the extracted light is released outside (to an upper side in FIG. 2) through the cathode serving as the semi-transmissive film.

When the organic EL device is of top emission type, the material of the anti-diffusion layer AD is not limited to ITO or IZO, and can be the other metallic materials except an insulating material as far as the diffusion of the Ag material can be inhibited.

1. An organic electroluminescent device comprising:
a glass substrate;
a thin film transistor disposed on the glass substrate;
an anti-diffusion layer disposed on the glass substrate and connected to the thin film transistor;
a first silver alloy layer disposed on the anti-diffusion layer;
an electrode disposed on the first silver alloy layer;
an organic electroluminescent layer disposed on the electrode; and
a second silver alloy layer disposed on the organic electroluminescent layer.

2. The organic electroluminescent device of claim 1, wherein the anti-diffusion layer is configured to prevent diffusion of silver atoms into the transistor.

3. The organic electroluminescent device of claim 1, wherein the anti-diffusion layer comprises indium tin oxide or indium zinc oxide.

4. The organic electroluminescent device of claim 1, wherein a thickness of the first silver alloy layer is configured so that the first silver alloy layer partially transmits and partially reflects light that is incident thereon, the electrode is made of indium tin oxide or indium zinc oxide, and a thickness of the second silver alloy layer is configured so that the second silver alloy layer does not transmit light that is incident thereon.

5. The organic electroluminescent device of claim 1, wherein a thickness of the first silver alloy layer is configured so that the first silver alloy layer does not transmit light that is incident thereon, the electrode is made of indium tin oxide or indium zinc oxide, and a thickness of the second silver alloy layer is configured so that the second silver alloy layer partially transmits and partially reflects light that is incident thereon.

6. The organic electroluminescent device of claim 1, wherein the organic electroluminescent layer comprises a hole transport layer, an emissive layer and an electron transport layer.

7. An organic electroluminescent device comprising:
a glass substrate;
a thin film transistor disposed on the glass substrate;
a first conducting inorganic layer disposed on the glass substrate and connected to the thin film transistor;
a first metal layer disposed on the first conducting inorganic layer;
a second conducting inorganic layer disposed on the first metal layer;
an organic electroluminescent layer disposed on the second conducting inorganic layer; and
a second metal layer disposed on the organic electroluminescent layer.
